(19) United States
(12) Patent Application Publication
(10) Pub. No.: US 2006/0267596 A1
(43) Pub. Date: Nov. 30, 2006

(54) Spring constant calibration device

(75) Inventor: Peter J. Cumpson, Teddington (GB)

Correspondence Address: DARBY & DARBY P.C., P. O. BOX 5257, NEW YORK, NY, 10150-5257, US

(73) Assignee: The Secretary of State for Trade and Industry of Her Majesty's Britannic Government, London (GB)

(21) Appl. No.: 10/557,275

(22) PCT Filed: May 18, 2004
(86) PCT No.: PCT/GB04/02134

§ 371 Date: Nov. 17, 2005

(30) Foreign Application Priority Data
May 21, 2003 (GB) 0311692.8
May 21, 2003 (GB) 0311693.6
Aug. 18, 2003 (GB) 0319460.2

(51) Int. Cl. G01R 35/00

(52) U.S. Cl. 324/601

(57) ABSTRACT

A calibration device is disclosed. A platform has a substantially planar surface suitable for the landing of an AFM cantilever tip, one or more supporting legs arranged to provide sprung resistance to the platform and a capacitive sensor for measuring the combined spring constant of the one or more supporting legs with respect to displacement substantially perpendicular to said substantially planar surface.

### FIELD OF THE INVENTION

The present invention relates to a calibration device suitable for calibrating small force measuring devices. In particular, the present invention relates to a calibration device in which accurate measurements under, and traceable to, the SI system can be obtained.

### BACKGROUND OF THE INVENTION

Measurements of small forces, in the nanonewton and piconewton range, have become important in recent years due to the widespread use of the Atomic Force Microscope (AFM) and associated instruments. There is a need to measure such small forces accurately, for example, protein-protein interactions or materials properties via the small force applied to an indenting tip.

Accuracy is rarely mentioned for AFM force measurements. AFMs measure displacement accurately, and are calibrated quite easily using step-height standards. Some AFM instruments even incorporate laser interferometry to make traceable height measurements.

The quantification of interaction forces is much more problematic. Force on the tip is inferred from the deflection of the cantilever, using an assumed value for the cantilever spring constant. The accuracy to which the spring constant is known is the limiting factor in the accuracy of a force measurement. Many methods have been proposed for calibrating the stiffness of an AFM probe, but none are traceable, and typical accuracy is only about 20-30%.

Reference artifacts for dimensional calibration of AFM have been available from many sources for ten years or more, but calibration of the force constant of AFM cantilevers is more troublesome. Uncalibrated cantilevers lead to very large errors in the measurement of nanonewton forces, such as in direct experiments to break individual covalent bonds by AFM, or the measurement of protein interaction forces. Commercial reference artifacts are available, but offer no traceability to the SI measurement system. This is important because there are two important methods of measuring nanoscale forces, AFM and optical tweezers. AFM is most conveniently calibrated using reference cantilevers, whereas optical tweezer forces are estimated based on the rate of change of photon momentum. Both methods are used, for example, in measuring bond-breaking forces. They must both have a common force scale, or burgeoning work in both areas will be difficult to build-upon. What is more, a traceable calibration method is now timely.

The reason is that the thickness of AFM cantilevers is difficult to control to the tolerance required to give them repeatable spring constants. The force constant for cantilevers from two different batches can vary by almost a factor of ten, because force constant is proportional to the cube of cantilever thickness, and the equipment for making them comes from the microelectronics industry where Si film thickness to this exquisite level is not a priority. This situation seems set to remain for the foreseeable future, meaning that an easy and accurate method of calibrating cantilevers would be very useful.

In addition, tip coatings can have a significant effect on spring constant that is difficult to model or predict.

A number of different methods have been suggested for the calibration of AFM cantilevers. Particularly effective is the use of a reference cantilever. Those methods that depend on measurement of the resonant frequency (or frequencies) of the cantilever are also attractive, because they are simple and do not risk damage to the cantilever. Unfortunately these resonance methods are problematic, for the following reasons;
Resonant frequencies give us only the ratio of the spring constant to an inertial term. The inertial term is often difficult to estimate because the mass of the cantilever is distributed, making the theory complex, especially due to the non-trivial shapes of AFM cantilevers designed for increased imaging performance.

Methods that rely on calibrating the cantilever by comparing the thermal vibration of the cantilever at a known temperature with the predictions of statistical thermodynamics are attractive due to the apparent experimental simplicity of this measurement, but are also problematic. It is often unclear, for example, how much of the power in the supposedly “thermal” vibration is in fact acoustic or mechanical noise from the environment. This can lead to the spring constant of cantilevers being systematically underestimated. Mechanical and acoustic noise must be excluded much more rigorously than is required for normal AFM operation, which spoils the apparent simplicity for the user.

| Class of Method | Method | Accuracy | Demerits |
|---|---|---|---|
| Dynamic response methods | Resonance frequency | ≈10% | Positioning and calibration of load |
| | with added mass | | difficult; potentially destructive |
| | Thermal fluctuations | 10-20% | Temperature control essential; only |
| | | | suitable for soft levers; requires |
| | | | analysis of resonance curve |
| | Simple scaling from | 5-10% | Depends on dimensional accuracy and |
| | resonance frequency | | determination of effective mass |
| Theoretical methods | Finite difference | 10%+ | Depends on dimensional accuracy and |
| | calculation | | Young's modulus |
| | Parallel beam approximation | 10%+ | Depends on dimensional accuracy and |
| | | | Young's modulus |
| Static response methods | Static deflection with | 15% | Positioning and determination of load |
| | added mass | | difficult; potentially destructive |
| | Response to pendulum force | 30-40% | Complex and time-consuming procedure |
| | Static deflection with external | 15-40% | Requires accurate external standard |
| | standard | | |

Reference cantilevers are commercially available. However, these are small and difficult to land the AFM tip on. One needs a separate optical microscope to measure the distance from the base of the reference cantilever to the tip—perhaps half of all AFM instruments do not have this. Even if they do, the accuracy with which this distance can be measured is not sufficient, because the spring constant of the reference cantilever depends on the cube of this distance: If one measures it to 3% uncertainty, the uncertainty in the calibration of the AFM cantilever is around 10%.

In the 1980's and 1990's a method of comparing mass standards to the SI system via electrical units, known as a Watt balance, was developed. Dimensional uncertainties are cancelled through the combination of static and dynamic experiments.

The apparatus used in Watt balance is normally a moving-coil inductive device. These Watt balances are sophisticated devices designed to achieve accuracies of around one part in 10⁸, for forces in the region of 1-10N, a very demanding requirement requiring metrological work of the highest order.

The essence of the Watt balance concept is to realise a known force in terms of traceable measurements of electrical quantities and linear displacement and velocity so that the physical mass defining the kilogram could be replaced with a repeatable experiment from which the weight could be accurately generated. A Watt Balance apparatus is used at the National Physical Laboratory in the United Kingdom. In particular, the apparatus is used for comparing masses of around 1 kg. A solenoid is used to apply a force by induction, and the current through the solenoid is measured. The solenoid is then moved, at a measured velocity, through a magnetic field of measured strength, and the voltage generated in the solenoid is measured. Combining these two sets of measurements—for the static and dynamic parts of the experiment—allows one to eliminate the uncertainty due to the poorly-known size of the solenoid (and even the particular path within conductors taken by currents flowing through the solenoid).

An electrical method of generating small forces would be much more practical than methods dependent on microscopic deadweights. However, to date no known device has been produced to the required dimensional accuracy suitable for use in this field.

### SUMMARY OF THE INVENTION

According to one aspect of the present invention, there is provided a calibration device comprising a platform suitable for the landing of an AFM cantilever tip, one or more supporting legs arranged to provide sprung resistance to the landing of an AFM cantilever tip and a capacitive sensor for measuring the combined spring constant (with respect to vertical displacement) of the one or more supporting legs.

The capacitive sensor may optionally also be used as an actuator, capable of setting the device into resonance.

In addition, the device may include a piezoelectric or other vibrator capable of setting the device into resonance.

A capacitive analogue of the “Watt Balance” method is used to produce a reference spring for the calibration of AFM cantilevers. The need to find a way of eliminating uncertainties due to the limited manufacturing tolerance of the actuator is even more important here than it is in the case of the large inductive version; though microfabricated devices are made with excellent dimensional tolerances in absolute terms, in fractional terms these are typically worse than for macroscale devices.

The device we have demonstrated has two “folded-beam” legs, and two interdigital comb drive capacitive actuators. Versions having one or three legs may be more mechanically stable in particular applications and therefore easier for the AFM user to use. Both one and three legged devices are under development. In addition, one or more comb drives can also be used. The device is fabricated on a silicon die by successive deposition of layers of polycrystalline silicon and silicon dioxide by chemical vapour deposition (CVD). The silicon dioxide is removed in a subsequent HF etch, leaving the released polycrystalline silicon structure. This process is commonly called surface micromachining in silicon.

The present invention seeks to provide a calibration device in which accurate measurements traceable to the SI measurement system can be made.

Methods of weighing masses of around one kilogram using an electromagnet are known. These methods use large instruments aimed at weighing masses of around 100 g to 1 kg as a primary standard of mass to replace the international prototype kilogram and are not suitable for use in AFM or with small forces. However, these methods are accurate and traceable to the SI system.

According to another aspect of the present invention, there is provided a method of determining a spring constant of an AFM cantilever comprising determining deflection of the cantilever when pressed against a solid surface, determining deflection of the cantilever when pressed against a calibration device having a predetermined spring constant and calculating the spring constant of the AFM cantilever from the ratio of the two deflections multiplied by the predetermined spring constant.

The method may include the step of determining the predetermined spring constant using a Watt balance on board the calibration device.

Combining static and dynamic measurements of the resonance of the calibration device including a Watt balance it is possible to measure the spring-constant of the legs that support it. This device can then be used as a reference spring to calibrate AFM cantilevers.

Particular advantages of the calibration device according to the present invention include higher precision in spring constant calibration than is possible with existing reference cantilevers, precision increasing by up to a factor of about ten and accurate traceability to the SI system.

The device allows AFM cantilevers to be calibrated quite easily, to an uncertainty of ±5% at one standard deviation. A simple substitution of the analogue velocimeter used in this work with a digital model should reduce this uncertainty to around ±2%. Both are significant improvements on current practice, and allow traceability to the SI system. It is envisaged that the method of calibrating the spring constant described here, rather than be used to produce a calibrated reference spring against which AFM cantilevers may be calibrated, will ultimately be “built-in” to AFM cantilevers themselves (for example by adding comb drives at each side of the cantilever). An entire wafer of microfabricated AFM cantilevers, perhaps containing hundreds of cantilevers, could be calibrated using our non-contact method (combining electrical and interferometric measurements) quickly and easily by the manufacturer.

The calibration devices according to the present invention are very robust with respect to mechanical shock and vibration because of their exceptionally small interia. Such devices could, for example, be sent through the post without any problems. By comparison, if a large device was to be manufactured (perhaps greater than a cubic centimetre in volume) for applying small forces to an AFM cantilever, the large mass of this device would require better vibration isolation than required for general AFM use, and therefore would not appeal to the AFM practitioner as a practical method of spring constant calibration. However, the microfabricated device of the present invention is just as fragile as AFM cantilevers themselves when it comes to handling—both would be destroyed if accidentally touched. In addition, the Watt Balance device should be protected from the ingress of dust particles under the reference springs. Protection is preferably achieved by covering the Watt Balance chip with a glass cover slip when not in use.

A number of the calibration devices with differing spring constants may be provided on an array to allow calibration of a wide range of devices.

According to another aspect of the present invention, there is provided a reference cantilever, for use in calibration of small force measuring devices such as AFM cantilevers, the reference cantilever including a length scale visible in AFM images. The length scale essentially eliminates the greatest source of uncertainty in calibration—location of the position of the AFM tip along the length of the cantilever. The present invention seeks to substantially eliminate this uncertainty and minimise errors in determining location of the AFM tip along the length of the reference cantilever.

The length scale may comprise a code, preferably a binary code, is etched into an oxide layer on the surface of the cantilever. The oxide layer is preferably sufficiently thin that it does not significantly change the mechanical behaviour of the cantilever. The code is used as a precise ruler, allowing a 100×100 micrometre view of the surface (this is typically the maximum an AFM will allow) to define the position of the tip to an uncertainty of 100 nm or less. The code is visible in AFM images because it has sufficient topography (the squares are about 0.2 micrometres high) and in optical and electron microscopes.

Preferably, the reference cantilever used is larger than used hitherto. In a preferred embodiment 1.6 mm long, which provides sufficient air-damping to measure the binary pattern by AFM imaging, while presenting a known spring constant when one presses more slowly using an AFM tip to calibrate an AFM cantilever.

Preferably, the reference cantilever includes built-in piezoresistors that allow electrical monitoring of its mechanical resonant frequencies. This gives a useful indication of damage to the cantilever that would otherwise cause a calibration error. There are two possible uses of these piezoresistors. They may simply be used to monitor the fundamental frequency of the reference cantilever prior to AFM calibration; a change of 2% or more may represent a significant change in the mass or spring constant of the reference cantilever, indicating that it should be replaced. Also, these piezoresistors allow an electrical measurement of several modes of the reference cantilever while shaking the entire chip containing the reference cantilever using (for example) a piezo-actuated stage. Measurement of several mode frequencies allows one to deduce the thickness of the membrane from which the cantilever is constructed, and therefore calibrate the reference cantilever itself. This could also be done by external interferometric methods (e.g. the Doppler method described later) but an electrical measurement via the current through the two piezoresistors will be quicker and more convenient in most cases.

By using the reference cantilever of the present invention, higher precision in spring constant calibration can be achieved. In comparison with existing reference cantilevers, the precision could be as much as a factor of about ten greater.

Particular benefits found from use of the present invention include:
Elimination of location along reference cantilever uncertainty in AFM spring-constant calibration by the “cantilever-on-cantilever” method
The large surface area of this reference cantilever, relative to the accuracy of the gross-approach mechanism of most APM stages, makes landing the AFM tip on the reference cantilever easy.
Errors due to partial torsional displacement of the cantilever are avoided by moving the AFM tip to the mid-line of the length-scale after contact.
The relatively large area of the reference cantilever means that its resonant frequency is low (around 1.4 kHz). Nevertheless, AFM images of the length-scale on the cantilever are free of noise arising from the excitation of the reference cantilever due to effective air-damping, again due to the relatively large surface area of the reference cantilever.
Precision of around ±3% in the calibration of AFM cantilever spring constant, and an accuracy when expressed in SI newtons of around ±10% at the 1SD level.
Quick and easy calculation of the spring constant of AFM cantilevers.

### BRIEF DESCRIPTION OF THE DRAWINGS

Examples of the present invention will now be described in detail, by way of example only, with reference to the accompanying drawings in which:

FIG. 1 is a three-dimensional computer model of a calibration device according to an embodiment of the present invention;

FIG. 2 is a cross section taken diagonally across the calibration device of FIG. 1

FIG. 3 is a schematic diagram illustrating aspects of the device of FIG. 1 when in operation;

FIG. 4 illustrates the use of the calibration device of FIG. 1;

FIG. 5 illustrates a system used to obtain more accurate calibration measurements;

FIG. 6 is a graph showing Vertical displacement of microfabricated Watt Balance platform as a function of potential applied to the fixed comb fingers. The platform is at earth potential;

FIG. 7 is an optical micrograph of the Watt balance actuator;

FIG. 8 is a graph plotting peak-to-peak velocity (as measured by the Doppler method) and current through the device (including parasitic capacitances) in the vicinity of the mechanical resonance of the Watt Balance;

FIG. 9 is a graph plotting ratio S against frequency in the vicinity of the mechanical resonance of the Watt Balance;

FIG. 10 is a graph showing the data plotted in FIG. 8, smoothed over a 20 Hz interval;

FIG. 11 illustrates a method of calibrating an AFM cantilever using a calibration device according to the present invention;

FIG. 12 is a view from above of a silicon die containing reference cantilevers according to an embodiment of the present invention;

FIG. 13 is a schematic vertical cross-section through the length of the cantilever of FIG. 12;

FIGS. 14a-c show an example of a binary code suitable for use in a reference cantilever such as that illustrated with reference to FIG. 12;

FIG. 15 illustrates the decoding process used to determine the position from a five-bit version of the binary code incorporated in the oxide layer on the top surface of the cantilever;

FIG. 16 is a montage of scanning electron microscope (SEM) images of the microfabricated device containing the reference cantilever using a primary energy of 20 keV;

FIG. 17 shows topographic images of 200 μm×100 μm areas from the top of the die (beside the cantilever, and therefore having a similar surface roughness) and the underside of the cantilever (the surface that was bulk etched);

FIG. 18 illustrates modes of vibration of the cantilever identified using a Doppler laser vibrometer system;

FIG. 19 shows the fundamental resonance for two different background pressures of 3 Pa and 10 Pa;

FIG. 20 shows experimentally measured modes of vibration of the reference cantilever;

FIG. 21 shows experimental determinations of higher order modes of vibration of the reference cantilever;

FIG. 22 shows the first two modes of vibration of the doubly-supported beam, determined experimentally by Doppler vibrometry;

FIG. 23 is an image acquired after landing the AFM tip on the surface of the reference cantilever; and,

FIG. 24 is a log-log plot of (m−1) against (L₀/L) to give a straight line of gradient −3 and intercept (k_{c}/k_{E}) for two cantilevers, of nominal spring constant 0.5N/m and 2N/m.

### DETAILED DESCRIPTION

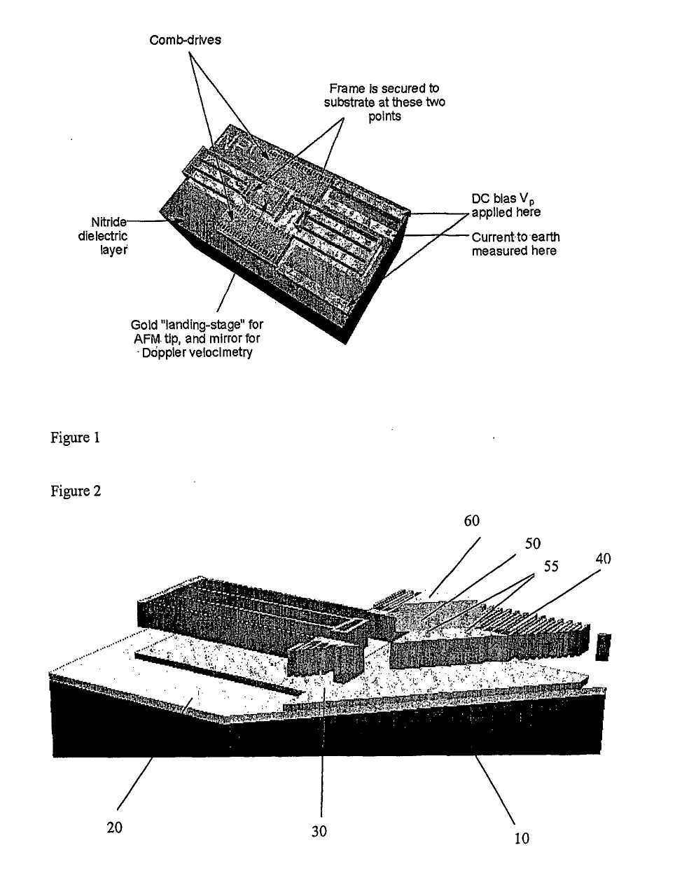

FIG. 1 is a three-dimensional computer model of a calibration device according to an embodiment of the present invention. The area shown is 980 by 560 microns. Dimensions perpendicular to the plane have been expanded by a factor of 20 for clarity.

In this embodiment, the Watt balance principle is applied in an entirely different context. The calibration device includes a microfabricated capacitive Watt balance for use in AFM spring-constant calibration.

FIG. 2 is a cross section taken diagonally across the calibration device of FIG. 1 The measurement of the spring-constant of these two legs represents the calibration required.

In this embodiment, the substrate 10 is a 250 microns thick Si layer. There is then a silicon nitride layer 20 about 0.5 microns thick followed by a layer 30 of highly-doped (and therefore conductive) polycrystalline silicon. Comb drives 40 (one of which is illustrated in FIG. 2, although there could be any number) are also formed from the highly doped polycrystalline silicon, as is the calibration device 50. The calibration device 50 includes a plurality of flexible legs 55, of which two are shown. Finally, in a preferred embodiment, right at the top of the device is a rectangular gold mirror 60.

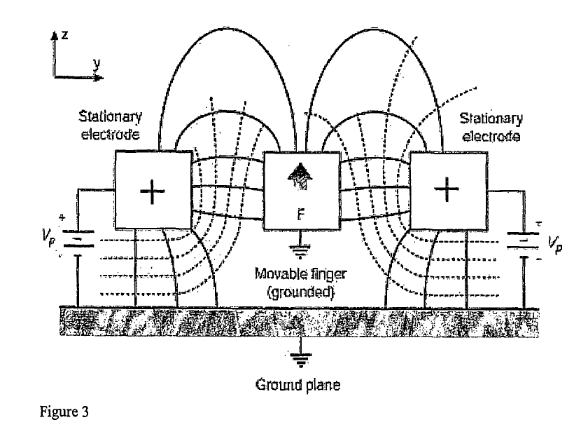

FIG. 3 is a schematic diagram illustrating aspects of the device of FIG. 1 when in operation. The AFM Landing Stage is “levitated” due to asymmetry in the electric field surrounding the interdigital electrodes due to the earthed, doped polysilicon groundplane. Field lines are shown continuous lines, while isopotentials are shown as broken lines.

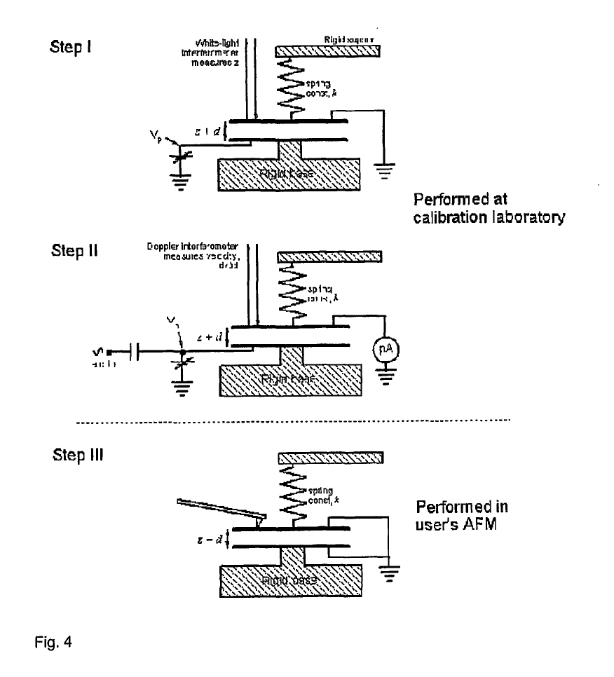

FIG. 4 illustrates a calibration method using the above described device. In steps I and II, static and dynamic measurements of the displacement of a moveable capacitor plate (the comb drive(s)), together with electrical measurements, allow the spring constant of the spring supporting that moveable plate to be measured, potentially traceable to the SI. In step III this spring is then used as a reference spring within the AFM to calibrate the spring constant of the cantilever under test, without further electrical or other measurement.

The device is essentially a capacitor with one fixed electrode and one moveable electrode. The moveable electrode is suspended on a spring having a spring constant similar to that of the AFM cantilever to be calibrated. The calibration comprises three steps. Steps I and II require special electrical and interferometric measurements, and will typically be performed in a calibration. The results of steps I and II give the spring constant of the spring supporting the moveable electrode. The entire device is then earthed, and sent to the AFM user. To the AFM user this is simply a reference spring, and the static deflection of the AFM cantilever under test is then used to measure the spring constant of that cantilever.

An important point to make at this stage is that the method involves no physical contact—the calibration of the reference spring requires only electrical and interferometric measurements.

An applied voltage leads to an increased separation between substrate and the AFM landing-stage. A simple parallel-plate capacitor could be used, but suffers the danger of the plates being attracted and sticking together.

The substrate groundplane under the device is always earthed, and is connected directly to the moving part of the device via the two legs. Therefore the comb drive fingers that move up and down are always at 0V. As we apply a voltage to the fixed fingers the field around them is not symmetrical above and below them—because of the earthed groundplane. This asymmetry means that the movable fingers see more of the field above them than below them, and are attracted upwards.

The comb drives are only used during calibration of the calibration device itself and the AFM user, upon purchasing the calibration device does no electrical measurement or even any electrical connection. To the user, the device is just a platform which, when pressed with an AFM tip, responds with a known force per unit distance of downward displacement—i.e. a reference spring.

The Watt Balance in electrical terms is a two-terminal device: the fixed outer digits of the comb-drives are at a fixed potential Vₚ, while current to earth is measured from the structure formed by the movable frame and fixed groundplane under it, which are in electrical contact

During calibration of the calibration device, the comb drives are used as follows. Firstly, a small AC potential applied to them at the resonant frequency of the Watt Balance (for example, 4.2 kHz) sets the Watt Balance into resonance. Small AC voltages are used giving a vibration amplitude of about 70 nm. As well as being used as an actuator in this way (and in fact one can use an external piezo shaker if one does not want to use the comb drives as actuators) we use the comb drives to sense the gradient of capacitance of the Watt Balance, by placing a DC voltage (Vp in FIG. 3) on the fixed comb fingers and monitoring the current to earth from the moving fingers as the capacitance changes in step with the displacement of the moving fingers. Together with a separate measurement of static displacement as a function of voltage, this capacitance gradient gives us the force required to displace the platform upwards by a known distance and hence the spring constant of the legs supporting it.

Although the comb drive is geometrically complex, it is just a two-terminal capacitor electrically. One particular advantage lies in the fact that it separates when a voltage is applied, whereas a parallel-plate capacitor (above a certain “pull in” voltage) snaps together destructively. Given the layer-wise constraints of MEMS fabrication, the comb drive method described above is one of the few structures robust to this “pull-in” effect, at least for moderate voltages.

Preferably, the device incorporates a mirror on the AFM landing-stage to simplify measurement of vertical displacement and velocity by optical interferometry and Doppler velocimetry respectively. In the present embodiment, the device was fabricated using the three-layer polysilicon surface micromachining MUMPs (Multi User MEMS) process.

Prior to manufacture, the spring constant of the calibration device, k_{ref}, is selected to be approximately equal to the spring constants of the AFM cantilevers to be calibrated, since this leads to the greatest accuracy when comparing the spring constant of the AFM cantilever with that of a reference. After manufacture the exact value of this spring constant is measured by a combination of electrical measurements and interferometry (preferably Doppler interferometry) using the Watt Balance method we describe here. This calibration will typically be carried-out by a specialised calibration department or laboratory. The calibrated device can then be sent out to the AFM user, typically with a calibration certificate stating the value of the spring constant. Often it will be useful to distribute a number of such devices together on the same chip, covering a range of different spring constants. The calibration device is then used by the AFM practitioner as a reference surface for AFM spring constant calibration. The cantilever of the AFM is applied against a hard surface such as the neighbouring area of the chip holding the calibration device consisting of silicon 0.4 mm thick. Since this surface is rigid, the increased deflection of the tip during acquisition of a force-distance curve is equal to the downward displacement of the cantilever by the tube scanner of the AFM.

The cantilever is then applied against the reference surface of the calibration device. The spring constant of the AFM cantilever can be calculated from the ratio of the two displacement slopes and the known value of the calibrated reference, k_{ref}.

As the spring constant of the calibration device (k_{ref}) is traceable to realisations of SI electrical quantities, the spring constant of the AFM cantilever can also be determined to the same level of traceability.

Determination of Spring Constant of the Calibration Device

This is the calibration step typically carried out in a specialised laboratory or calibration facility. As with the macroscopic Watt Balance, there are static and dynamic measurements to be made. Both must be performed in vacuum to avoid air-damping (the dynamic measurement operates at low Reynolds number) and to avoid attracting dust particles to critical parts of the electrostatic comb-drive.

The most important quantity to be measured is the gradient of capacitance as the landing-stage is displaced. If we know the gradient of capacitance, we can calculate the force on the comb-drives, and therefore the balancing mechanical force exerted by the supporting folded springs. We can measure the displacement, and so we can calculate the ratio of applied force to displacement—i.e. the spring constant. This static measurement is relatively straightforward, but we still need to measure the gradient of capacitance, since for all but very special geometries (such as that of the Thompson-Lampard capacitor) it cannot be calculated from the geometry of the device with sufficient accuracy. Indeed the constraints and relatively poor fractional dimensional accuracy of surface micromachining make this calculation more difficult and inaccurate than for many conceivable macroscopic versions. One could measure the capacitance gradient in two ways;
Using a sensitive capacitance bridge to make direct measurements of the device capacitance at a number of static displacements. This would give very precise capacitance values, including a constant stray capacitance originating from the fixed parts of the device. To obtain the gradient of capacitance one would need to differentiate with respect to the measured displacement, increasing the uncertainty budget, but capacitance bridges have now reached such a high level of precision that this approach is viable, even for the very small capacitance of a surface micromachined comb drive.
Alternatively, one can “dither” the displacement of the landing-stage, either mechanically (e.g. using a small piezo actuator under it), by superposing a very small a.c. drive on the d.c. potential applied to achieve a particular static displacement. The mechanical vibration causes a time variation in capacitance leading to a measurable a.c. current. By simultaneously measuring the velocity of the landing-stage one can calculate the gradient of capacitance required.

The second of these two methods corresponds to the Watt Balance approach. We chose this approach because (a) one can take advantage of the sharp mechanical resonance of MEMS devices to make the “dither” procedure distinguish very clearly between the nuisance of stray electrical capacitance and the important displacement-related capacitance gradient, and (b) capacitance bridges of sufficient sensitivity also capable of dealing with a range of d.c. bias were not commercially available.

In the present embodiment, displacement and velocity measurements are made using an instrument that has not been calibrated traceably, but comes from a class of Doppler velocimeter that can be made traceable: Doppler vibrometers using digital demodulation are accepted for traceable primary velocity calibrations according to the ISO 16063: Methods for the calibration of vibration and shock transducers—Part 11: Primary vibration calibration by laser interferometry. It will however be appreciated that other instruments could be used.

There are static and dynamic measurements to be made. Both are preferably performed in vacuum to avoid air-damping (the dynamic measurement operates at low Reynolds number) and to avoid attracting dust particles to critical parts of the electrostatic comb-drive.
1. Static measurement (shown schematically in FIG. 4, step I). This consists of measuring the static displacement of the AFM landing-stage as a function of applied voltage.
2. Dynamic measurement (shown schematically in FIG. 4, Step II). This consists of measuring the current to earth passing through the device, while simultaneously measuring its vibration velocity using Doppler velocimetry. The extremely sharp resonance of the Watt Balance platform, when operating in vacuum, allows us to separate the change in capacitance of the device due to mechanical displacement from the inevitable parasitic capacitances elsewhere in the circuit.

By applying a DC voltage across the comb drives of the device, and setting it into resonance in its fundamental mode (either by adding a small AC component, or external mechanical shaking), one can simultaneously measure the velocity amplitude of vibration (typically <1 mm/s) and the electrical current through the device (typically <100 pA). Together these allow one to determine the gradient of the capacitance of the device at this DC bias.

Static Measurement

This consists of measuring the static displacement of the AFM landing-stage as a function of DC bias voltage. We measured this static displacement using white-light interferometry using a Zygo NewView 5020 interferometer. This measurement allows us to balance the electrostatic force on the comb drives (which depends on the capacitance gradient measured in the Dynamic Experiment, and which would otherwise not be known to sufficient accuracy) with the mechanical force arising from a measured displacement of the legs. This allows the spring-constant of the folded spring legs to be found.

The static deflection of the platform is the result of the balance between the elastic restoring force applied by the folded springs and the electrostatic force from the comb-drives. The stored electrostatic field energy is

$$E = \frac{1}{2} {CV}_{p}^{2}$$

where C is the capacitance, and Vₚ is the potential difference across it. The electrostatic force, F_{elec}, is

$${F}_{elec} = \frac{1}{2} \frac{\partial C}{\partial z} {V}_{p}^{2}$$

which balances an elastic force, F_{elastic} of;
F_{elastic}=kZ
where z is the static deflection, so that if we plot S against frequency in the region of the resonance, where

$$S = \frac{( i - \overline{i } ) {V}_{0}}{2 \overline{z} {v}_{doppler}}$$

v_{doppler} is determined in the dynamic experiment discussed below, and \overline{i} is the average of the current amplitude far below and far above the resonance (typically between 5 and 10 times the full-width at half maximum height of the resonance). We expect a sigmoidal curve of step height 2k, where k is the spring constant we wish to measure.

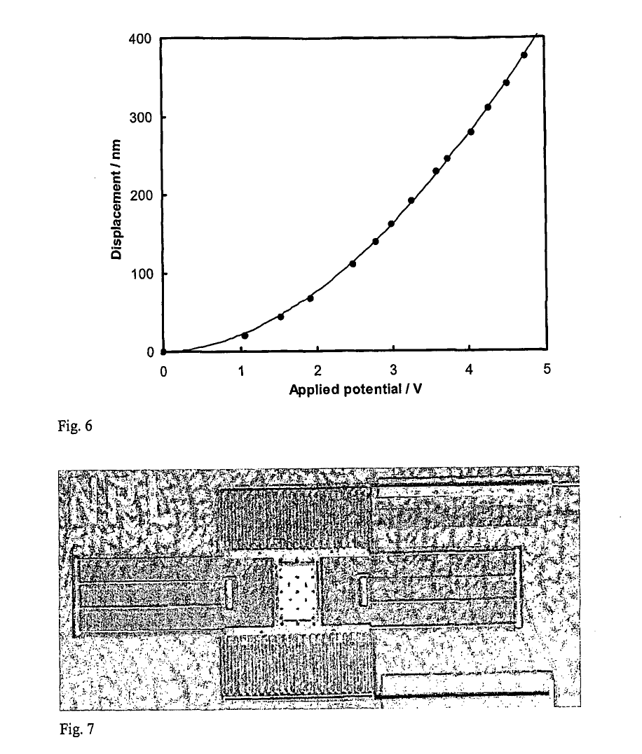

FIG. 6 is a graph showing Vertical displacement of microfabricated Watt Balance platform as a function of potential applied to the fixed comb fingers. The platform is at earth potential.

Dynamic Measurement

This consists of measuring the current to earth passing through the device, while simultaneously measuring its vibration velocity using Doppler velocimetry. The extremely sharp resonance of the Watt Balance platform, when operating in vacuum, allows us to separate the change in capacitance of the device due to mechanical displacement from the inevitable parasitic capacitances elsewhere in the circuit.

The current through the Watt Balance and the height of the mirror were recorded simultaneously and averaged to reduce noise using a Hewlett-Packard 3562A Dynamic Signal Analyser. These data were downloaded from to a PC computer.

Current through the device was measured using a CyberAmp 320 Signal conditioner with type 403 preamplifier (Axon Instruments Inc.). By using it in “virtual-earth” configuration, any parasitic capacitance across the input of the amplifier (or between the moving part of the actuator and the die substrate) connects virtual earth to earth, so its influence on the circuit operation is insignificant. In addition, the signal path from the Watt Balance actuator was carefully surrounded on the printed circuit board (PCB) by an earthed “guard” track, to minimize the effect of small stray currents across the bare PCB surface, for example due to any small surface contamination by electrolytes.

The Watt Balance devices tend to resonate at around 4.2 kHz, with a Full Width at Half Maximum (FWHM) of around 7 Hz at a background pressure of 2.3 Pa. This corresponds to a quality factor for this resonance of Q≈600. Since the device has a large cross-sectional area in the direction of displacement, this quality factor is rapidly reduced by air-damping at higher pressures. Therefore the calibration of the Watt balance springs must be performed in vacuum. Of course, the subsequent use of these springs to calibrate AFM cantilever, performed by the AFM user, will typically be in air or liquid.

The current through the device at resonance is equal to the rate of change of the product of its capacitance and the voltage across it.

$$i ( t ) = \frac{ⅆ ( {CV}_{p} )}{ⅆ t}$$

We consider also “stray” or “parasitic” capacitances, which we will call Cₚₐᵣₐ.

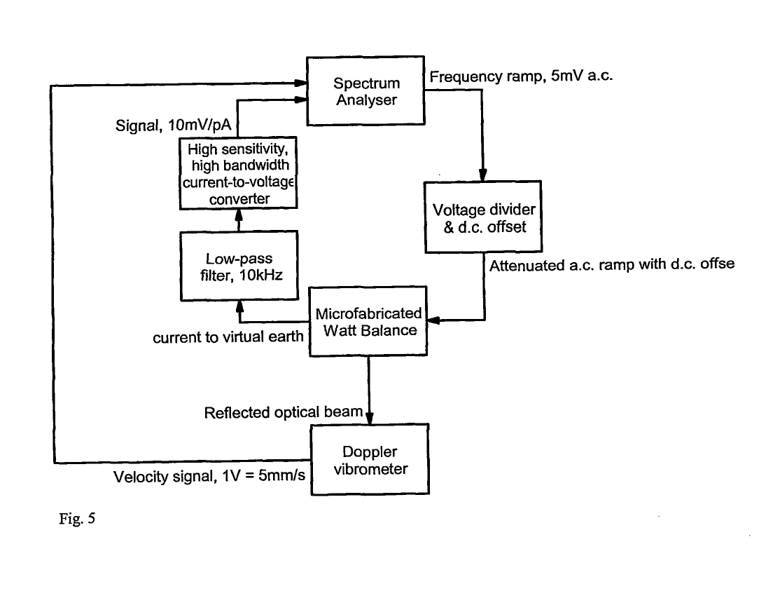

FIG. 5 illustrates a system used to obtain accurate calibration measurements.

Separating the capacitance of the device into two parts:
a. The dynamic capacitance, C(z), which changes as the platform is displaced, and
b. The static or parasitic part, Cₚₐᵣₐ. This is the capacitance between fixed parts of the device, for example adjacent tracks and pads on the silicon die.

Measuring the response of the device over a narrow frequency interval around the mechanical resonance, the static capacitance is expected to be constant, but the dynamic capacitance will vary with the motion of the platform.

$$i ( t ) = [ C ( z ) + {C}_{para} ] \frac{ⅆ {V}_{p} ( t )}{ⅆ t} + {V}_{p} ( t ) \frac{\partial C ( z )}{\partial z} \frac{ⅆ z}{ⅆ t}$$

Applying a d.c. potential of V₀ to the stationary part of the comb drives, together with a small a.c. component v(t), so that
Vₚ(t)=φ₀+v(t)

The purpose of the small a.c. component is to apply a small drive to the device, which, if this drive voltage is close to its mechanical resonant frequency, will cause it to vibrate mechanically with significant amplitude. Typically φ₀ is chosen in the range 1 to 4V, and v(t) is a sinusoid of amplitude and v₀ chosen in the range 250 μV to 2.5 mV.
v(t)=v₀ sin(ωₜ)

Now the velocity of the platform can be measured by Doppler velocimetry. At each instant we have a measurement of the velocity V(t)=V₀ cos(ωt+θ) of the platform. For a given amplitude of a.c. drive, both the amplitude V₀ and phase with respect to that drive (θ−π/2) vary as the drive frequency passes through resonance. We identify the Doppler velocity with the velocity (dz/dt) that appears above to give

$$i ( t ) = [ C ( z ) + {C}_{para} ] \frac{ⅆ v ( t )}{ⅆ t} + [ {ϕ}_{0} + {v}_{0} sin ( ω t ) ] \frac{\partial C ( z )}{\partial z} V ( t )$$

For a particular bias voltage φ₀, and an a.c. component amplitude v₀ sufficiently small that the capacitance C(z) varies linearly over the range of mechanical vibration, we obtain,

$$i ( t ) = [ C ( z ) + {C}_{para} ] {v}_{0} ωcos ( ω t ) + {ϕ}_{0} \frac{\partial C ( z )}{\partial z} V ( t )$$

The first term on the right hand side of the above equation represents a parasitic capacitive current that is constant in amplitude for frequencies near the mechanical resonance, and (π/2) radians in advance of the a.c. drive signal. The second term is the interesting one, because it is proportional to the capacitance gradient we wish to measure. This term has the same phase as the velocity of the mirror platform (and comb drives). At low frequencies the mirror displacement is in phase with the drive signal, whereas far above the resonance it lags by π radians. Therefore the velocity is (π/2) radians in advance of the a.c. drive voltage far below the resonance,

$$i ( t ) = [ C ( z ) + {C}_{para} ] {v}_{0} ωcos ( ω t ) + {ϕ}_{0} \frac{\partial C ( z )}{\partial z} {V}_{0} cos ( ω t ) , \\ for ω ⪡ {ω}_{r}$$

and lags by π/2 radians far above it,

$$i ( t ) = [ C ( z ) + {C}_{para} ] {v}_{0} ωcos ( ω t ) - {ϕ}_{0} \frac{\partial C ( z )}{\partial z} {V}_{0} cos ( ω t ) for ω ⪢ {ω}_{r}$$

where ωᵣ=2πfᵣ is the angular frequency of the mechanical resonance. The sharp mechanical resonance allows us to measure the magnitude of the second as this phase change occurs, since the first term is essentially constant over this narrow frequency interval.

As the driving frequency increases through the resonant frequency the two terms in the equation above are at first in-phase, and finally out of phase, leading to the step observed in the quantity S. The magnitude current change gives us the gradient in capacitance;

$$\frac{\partial C ( z )}{\partial z}$$

which as discussed above, is all we need to obtain a value for the spring constant of the device using the static experiment results. This is neatly summarized in the plot of the quantity S, though more sophisticated fitting to the curves shown in FIG. 7 (possibly also incorporating phase information) are likely to be ultimately more accurate.

FIG. 6 shows Zygo white-light interferometry measurements of vertical displacement of the Watt Balance platform as a function of the potential applied to the fixed comb fingers. This was performed in vacuum, residual pressure being measured as 2.3 Pa.

A complete analysis involved fitting data to an electrical equivalent circuit model, for which a signal analyzer with four channels would be necessary to achieve the most accurate results. However, since the resonance of this MEMS structure is so sharp, compared to the slow variation in parasitic capacitance with frequency, the transition from “in-phase” to “anti-phase” addition of current offers us a good way to gain insight into the measurement of the spring-constant. First, defining an expression for the spring constant k by balancing electrostatic and elastic forces on the platform,

$$k = \frac{{ϕ}_{0}^{2}}{2 \overline{z}} \frac{\partial C}{\partial z}$$

where \overline{z} is the time-average of the displacement z. An expression for the gradient of capacitance (∂C/∂z) gives

$$\frac{\partial C}{\partial z} = \frac{{i}_{0} {{\vert}_{ω ⪢ {ω}_{r}} - {i}_{0} \vert}_{ω ⪡ {ω}_{r}}}{2 {ϕ}_{0} {V}_{0}}$$

where the current amplitudes that appear at the top right hand side of the equation represent the measured current amplitude above and below resonance respectively. Using this to substitute for the capacitance gradient appearing in the previous equation we obtain,

$$k = \frac{{ϕ}_{0}}{4 \overline{z} {V}_{0}} ( {i}_{0} {{\vert}_{ω ⪢ {ω}_{r}} - {i}_{0} \vert}_{ω ⪡ {ω}_{r}} )$$

A plot of a quantity as a function of frequency from this equation shows that the spring constant emerges naturally. We define the quantity S, where

$$S ( ω ) = \frac{{ϕ}_{0} [ {i}_{0} ( ω ) - {\overline{i}}_{0} ]}{4 \overline{z} {V}_{0} ( ω )}$$

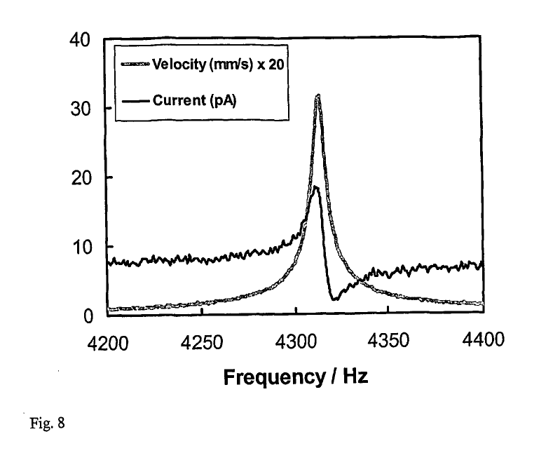

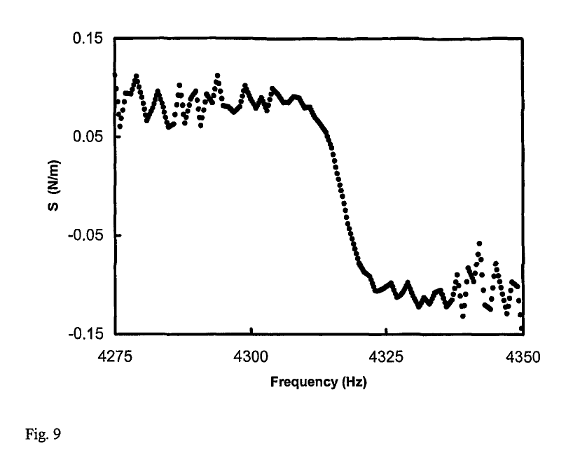

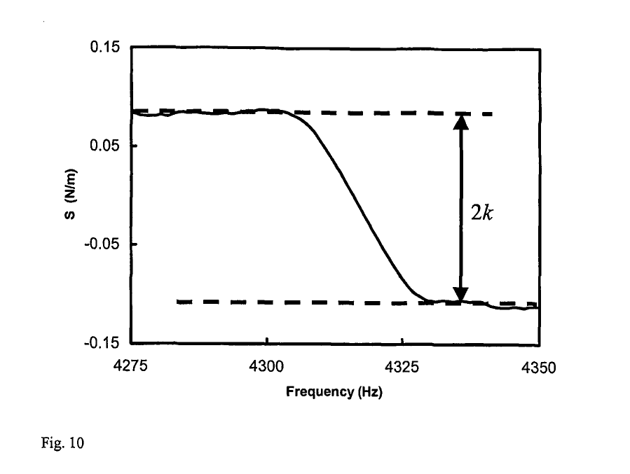

and \overline{i}₀ is the average current amplitude far from resonance (we used the average of the current measured 90 Hz above the resonance and 90 Hz below it, in each case averaging over an interval of 10 Hz centred on ±90 Hz). The function S has no special physical interpretation, except that when plotted as a function of frequency in the vicinity of the resonance it should exhibit a step equal to the spring-constant of the device. If we plot S against frequency in the region of the resonance, we should expect a sigmoidal curve of step height k, where k is the spring constant we wish to measure. FIG. 9 shows this data plotted for the current and velocity measurements of FIG. 8. There is a good deal of residual noise that could be improved by longer acquisition times than the five seconds this scan took. A 20 Hz running average smooth improves the plot considerably, as shown in FIG. 10. This gives us a spring-constant of 0.193±0.01 N/m, in reasonable agreement with an earlier, more approximate value of 0.23±0.03 N/m based on an estimate of the mass and resonant frequency of the vibrating part of the device.

Modes of Vibration

The microfabricated Watt Balance has a small capacitance, which can be implicitly measured by monitoring the current through the device as the comb drives move with respect to each other. This current is small, typically less than 100 pA, and therefore a number of precautions should be taken to make an accurate measurement. The mechanical resonance of the device assists us, by ensuring that (given the large quality factors we have measured in vacuum for this device) we can be confident that on-resonance the amplitude of vibration of other parts of the system are small compared to the amplitude of vibration of the device itself.

The Watt Balance actuator has many vibrational modes. To ensure that we attribute the correct mode of vibration to each of its resonant frequencies, measurements were made of the phase of vertical motion at a number of different points on the device. Because the device was vibrated vertically we do not see lateral modes.

| Mode | Frequency/kHz |
|---|---|
| Fundamental | 4.25 |
| Higher mode | 15 |

Note that in both of these vibrational modes the comb-drive displacement has the same phase throughout the length of the drive. Therefore both represent the same kind of vertical displacement as will occur when a normal force is applied to the center of the device by an AFM tip. Therefore, while in principle only one such mode would be necessary, in fact both modes can be used to determine the capacitance of the device as a function of the vertical displacement of the comb-drives.

FIG. 7 is an optical micrograph of the Watt balance actuator. Two comb-drives at the top and bottom of the picture apply “levitation” mode forces, leading to a displacement out of the plane of the photo. A folded spring mechanism provides a spring constant comparable to those of the AFM cantilevers to be calibrated. The central gold mirror can be seen clearly.

FIG. 8 is a graph plotting the velocity amplitude and current in the vicinity of the mechanical resonance of the Watt Balance.

FIG. 9 is a graph plotting ratio S against frequency in the vicinity of the mechanical resonance of the Watt Balance. The continuous curve is an average over 20 Hz. The step in this function gives the spring-constant of the device.

FIG. 10 is a graph showing the data plotted in FIG. 9, smoothed over a 20 Hz interval. The spring constant of the device is half the difference in S as one passes through the resonance.

The structural material used for the resonator is chemical vapour-deposited polycrystalline silicon. It is heavily doped to give a high conductivity, but it is conceivable that charges trapped close to its surface, perhaps at defects or grain boundaries, can add to the measured current during mechanical resonance. This would be analogous to the operation of the electret microphone, where a much larger charge on a vibrating membrane gives rise to a very easily measurable potential.

To check for the presence of trapped charges we reversed the polarity of the potential applied to the fixed section of each comb drive. As before, the moveable parts of the device are earthed. If significant trapped charges are present, their polarity will, of course, remain the same. If so we should observe a significant in the magnitude, not just the sign, of the measured current in the vicinity of the mechanical resonant peak in the frequency spectrum. If this is ever seen to be a problem one can construct the Watt balance device using Silicon-on-Insulator (SOI) technology in single crystal silicon. Operation would be essentially the same as for the polysilicon devices we have made.

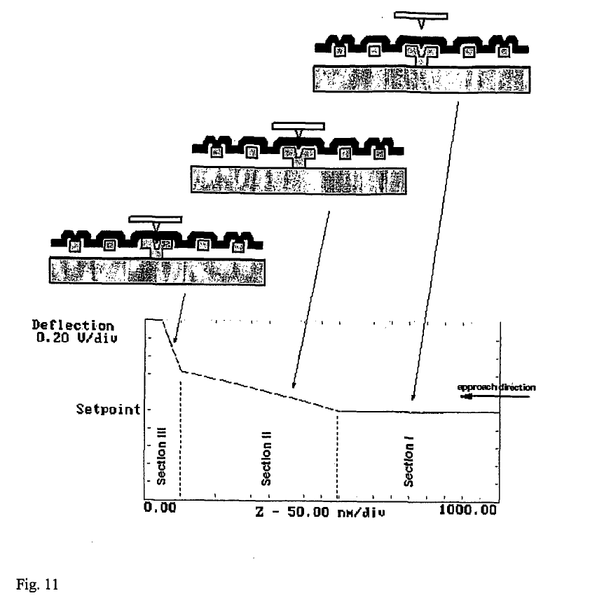

After the Watt Balance springs are calibrated using the above method, they can be distributed to AFM users. AFM users need not make any electrical measurements, but simply use these devices as calibrated reference springs. One method of calibrating AFM cantilevers using such reference springs is shown in FIG. 11 and is also illustrated in step III of FIG. 4. In FIG. 11, a single force-distance curve shows three distinct sections. The spring constant of the cantilever is simply the measured spring-constant of the Watt Balance multiplied by the ratio of the slopes of sections III and II of the force-distance curve.

The measurement of the spring constant of an AFM cantilever, k_{c}, is determined by comparison with the Watt balance spring constant, k. k_{c} can be found from the ratio of the slopes of the force-distance curve in Regions II and III, as follows,

$${k}_{c} = k [ \frac{( \frac{Δ {V}_{A - B}^{III}}{Δ {Z}^{III}} )}{( \frac{Δ {V}_{A - B}^{II}}{Δ {Z}^{II}} )} - 1 ]$$

where V_{A-B} is a potential difference representing the “A−B” signal from the four-quadrant detector of an AFM, and ΔV^{II}_{A-B}, ΔV^{III}_{A-B} are increments in the curves in regions II and III corresponding to displacement increments of ΔZ^{II}_{A-B} and ΔZ^{III}_{A-B} in the height of the piezo stage, respectively. The ratios (ΔV^{II}_{A-B}/ΔZ^{II}) and (ΔV^{III}_{A-B}/ΔZ^{III}) are simply the slopes of the curve in Region II (where the tip is in contact with the movable platform) and Region III (where the platform is also in contact with the substrate) respectively. The spring constant of the cantilever is simply the calibrated spring constant of the reference spring multiplied by the ratio of the slope of the force-distance curve in section III to that in section II, minus unity.

Although the lateral resolution of AFM is around 10 nm, it is typically very difficult to approach a target smaller than around 30 μm on a surface. This is due to the mechanics of the gross-approach mechanism of most AFM designs, relying on a stepper motor and a screw thread to lower the cantilever and tube scanner. This typically has some residual eccentricity that makes precise positioning of the tip prior to contact rather difficult. The Watt Balance device described above has a “landing area” of 80×109 μm. This is sufficiently large for the AFM user to approach without difficulty. Conversely, this means that the Watt Balance device cannot be made very much smaller than these dimensions without making it significantly more difficult to use by the AFM practitioner. It will always need to be a micro rather than a nano device.

Instead of using a Watt balance, one could, in principle, build a small parallel-plate capacitor, apply a known voltage to it, and obtain a small force traceable (via the electrical units) to the SI Newton. One plate of the capacitor would be fixed, and the opposite plate suspended above it on flexible springs having similar spring constant to those of the AFM cantilevers one wishes to calibrate. The dynamic part of the operation of the device as a Watt balance would require d.c. voltages to be applied to the capacitor causing the plates to approach. This must be controlled carefully, to avoid “snap-on”, where the movable plate comes into contact with the fixed plate, Van der Waals forces then making it almost impossible to separate them, effectively ending the useful life of the device. However the geometrical precision with which one can make such a small capacitor is limited, and this causes uncertainty in the forces generated by it. In addition, the Watt balance is inherently more stable and easier to control than a simple parallel-plate capacitor.

One could measure the gradient of capacitance using a capacitance bridge, eliminating the dynamic step.

In the future it will be possible to make AFM cantilevers with this system “built-in”, so that they can be manufactured on the scale of a silicon wafer, calibrated in turn and then sold. This is more convenient than having a separate calibration device. All AFM cantilevers need a partially reflective platform to operate the optical lever system. Thus, such a platform (or some other suitable part of the AFM structure) could be used in combination with one or more comb drives as described previously to provide an in-built calibration system.

A number of MEMS cantilever sensors are in development around the world that may, conceivably, require calibration and the calibration device described would be suitable for such a task.

The calibration device could be made by conventional machining or as a MEMS device. MEMS design has severe restrictions imposed by the layer-wise lithographic processes commonly used. Conventional machining is certainly capable of producing 5 to 10 mm-scale devices that can apply nanonewton forces, but they will also be susceptible to vibration due to large ratio of their weight to the forces they apply. Of course, careful vibration isolation can help a great deal, but often the result is a compromise in which some other aspect of performance is lost. What is more, the AFM user may well ask why they need better vibration isolation for cantilever calibration than they need for the AFM in normal use.

In contrast, MEMS devices can be made extremely small, with very small mass and much lower sensitivity to vibration.

Surface micromachining may also be used.

Electrostatic comb drives are typically the method of choice, and one can easily imagine an electrostatic Watt balance using such a comb drive. This would be suitable, for example, for the calibration of cantilevers in Lateral Force Microscopy. However we need a force perpendicular to the surface for the calibration of AFM spring constant.

In another embodiment of the present invention, a calibration device in the form of a reference cantilever is formed by bulk micromachining of silicon. Two separate reference cantilever structures, each nominally 3 μm thick, are fabricated from a single crystal silicon membrane. A binary code of surface oxide squares (easily visible in light, electron and atomic force microscopy) is formed in the surface of each cantilever, thereby making it easy to locate the position of the AFM tip along the length of the cantilevers. This is the main source of error when calibrating AFM using reference cantilevers, especially for those having spring constants greater than around 10N/m. The reference cantilever spans the range of spring constant (from 80N/m down to 0.03N/m) important in AFM, allowing almost any AFM cantilever to be calibrated easily and rapidly. One or more comb-drive actuators may be added to this device, to allow its calibration by the Watt balance method described above, thereby providing a reference cantilever whose spring constant is traceable to the SI.

A 3 μm epitaxial (i.e. single crystal) membrane was created by bulk back-side etching of silicon, in a foundry process similar to that used in the manufacture of membrane pressure sensors. An electrochemical etch-stop method was used to ensure a uniform and low-roughness membrane was created. Cantilever structures were created by cutting slits in the membrane by Deep Reactive Ion Etching (DRIE) to ensure that the sidewalls of the cantilevers are as near perpendicular to the surface as possible.

Two cantilevers were fabricated on the same chip, one being supported at one end only and one being supported at both ends (effectively a beam) for use in calibration of small and large AFM spring constants respectively. However, it will be appreciated that only one cantilever need be formed with support being provided according to the spring constant to be calibrated.

The cantilever structures were formed from a membrane of nominal thickness 3 μm, formed by electrochemical etch stop. This gave each cantilever a clean and smooth underside. The cantilevers were 150 μm in width and 1.6 mm in length, allowing AFM users to approach and land tips easily.

A binary “ruler” was formed in the surface of each cantilever and stretching the length of the cantilever. This allows accurate placement of an AFM tip at a point along the middle of the cantilever, and makes it straightforward to determine the exact position of the tip from an AFM image.

A glass substrate anodically-bonded to the underside of the wafer, to improve the robustness of the device when handling it by tweezers.

Surface piezoresistors were added near the base of the cantilever allow the monitoring of vibrations of the cantilever, if required.

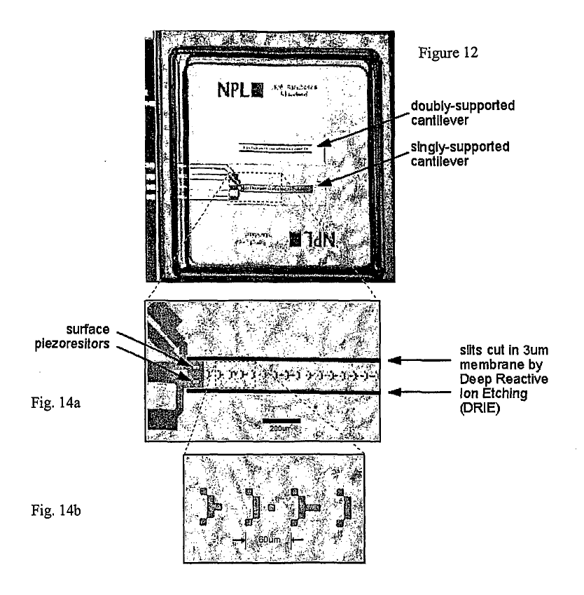

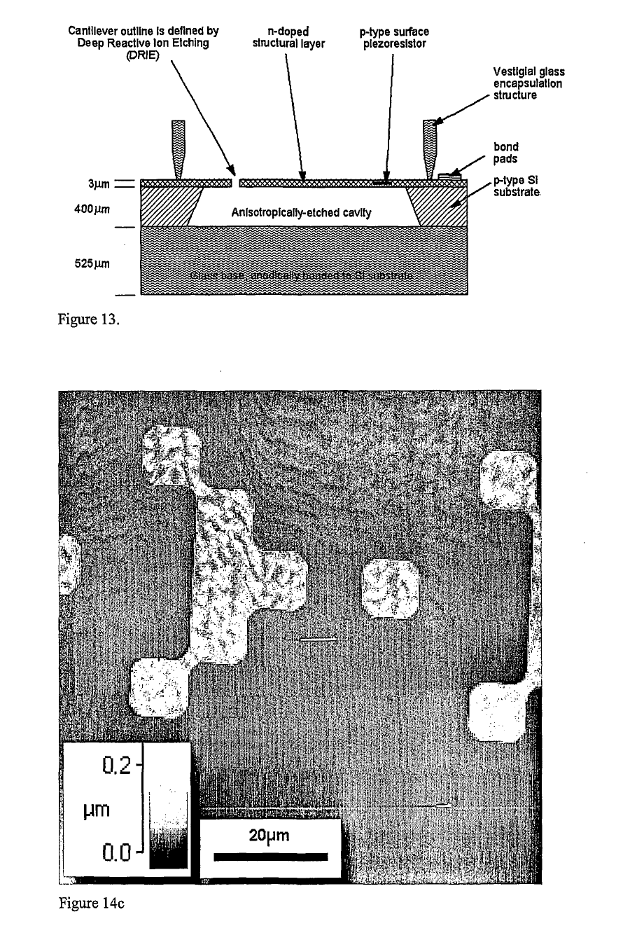

FIG. 12 is a view from above of the silicon die containing the reference cantilevers. This die is approximately 6 mm×6 mm, but smaller dies could be used equally well. A schematic vertical cross-section through the length of the cantilever is shown in FIG. 13. The long axis of the cantilever is aligned with the <111> crystallographic direction of the silicon

Particular care was taken to select a fabrication process that gives a uniform cantilever thickness. In bulk micromachining the implantation of an etch-stop layer (for example boron or oxygen) often fails to produce well-controlled thin membranes of the type required. A process incorporating an electrochemical etch-stop method was used to produce uniform and low roughness undersides for the reference cantilevers. A lightly-doped p-n junction was used as an etch stop by applying a bias between the wafer and the counter-electrode in the etchant. This method is known to give thickness uniformity of better than 1% in 10 μm membranes irrespective of etch uniformity or wafer-taper. The critical factor is dopant density in the first few micrometres of depth into the p-doped wafer; which over the 1.6 mm length of the reference cantilever is likely to be extremely uniform.

Integral Length Scale

The main source of uncertainty in the use of a reference cantilever for AFM calibration lies in the measurement of the displacement of the AFM tip along the length of this reference cantilever. Often the AFM user does not have an optical microscope capable of making this measurement accurately. Sometimes AFM is used with no optics at all. Therefore a length scale was incorporated into the surface of the cantilever. This had three aims;
To allow easy measurement of the position of an AFM tip from a local AFM image of the surface alone.
The scale should not change the mechanical properties of the cantilever significantly.
The scale should define the centre-line of the reference cantilever, so as to allow one to move the AFM tip to the middle of the reference cantilever in order to avoid errors due to inducing twisting of the reference cantilever.

One solution would be to etch a length scale in the cantilever surface resembling the scale of a ruler. However, it was found that there are not enough pixels within the AFM field of view to allow such a scale. Typically the largest scan-size available when using commercial AFM tube scanners is 100 μm×100 μm, so the entire information required to deduce the exact position of the AFM tip on the reference cantilever must be available from an image of this size or smaller.

An oxide layer on the upper surface was available for patterning into a length scale, but only at relatively low resolution, with a minimum feature size of 10 μm×10 μm. Therefore, a binary length scale was devised that contains sufficient information within the field of view of an AFM, and yet requires only 10 μm×10 μm squares. FIGS. 14a-c show an example of this binary code. The code can be read very easily by atomic force microscopy, optical microscopy or scanning electron microscopy.

FIG. 14c shows one of the binary length scales imaged by AFM. One concern prior to manufacture of the reference cantilevers was that their large size and consequently low resonant frequencies would result in excitation of the reference cantilever during imaging by AFM, making such images very noisy. In fact, despite the relatively low resonant frequency of the reference cantilever (around 1.41 kHz) no difficulty was experienced in imaging the scale. In fact, even close to the end of the reference cantilever there was no obvious degradation in image quality.

The scale consists of simple arrows made-up of 10 μm×10 μm squares and separated by 60 μm from the next arrow. Between successive arrows is a five-bit binary code defining the position for the arrow proceeding it. The length scale has a secondary purpose in defining for the AFM user a line running down the middle of the cantilever as it is known that deviation from this middle line when calibrating an AFM cantilever against a reference cantilever can lead to errors due to the partly torsional strain of the reference cantilever

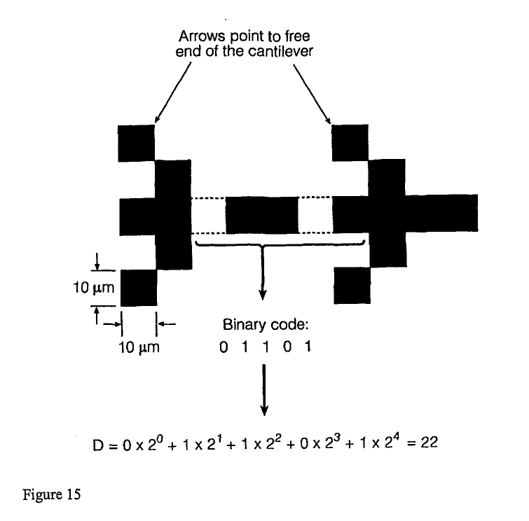

FIG. 15 illustrates the decoding process used to determine the position from a five-bit version of the binary code incorporated in the oxide layer on the top surface of the cantilever. In the illustrated example, bit positions 2, 3 and 5 are found to be occupied indicating a position of 22. As this is a binary scale, the first position is 0000 and therefore this is the 23^{rd} position. This correlates to a position of 1380 μm (23×60 μm) from the start of the scale.

The clarity of images such as this allows easy positioning of the AFM tip to an accuracy of around 100 nm prior to acquiring a force-distance curve. This has been found to virtally eliminate the position measurement error in calibration.

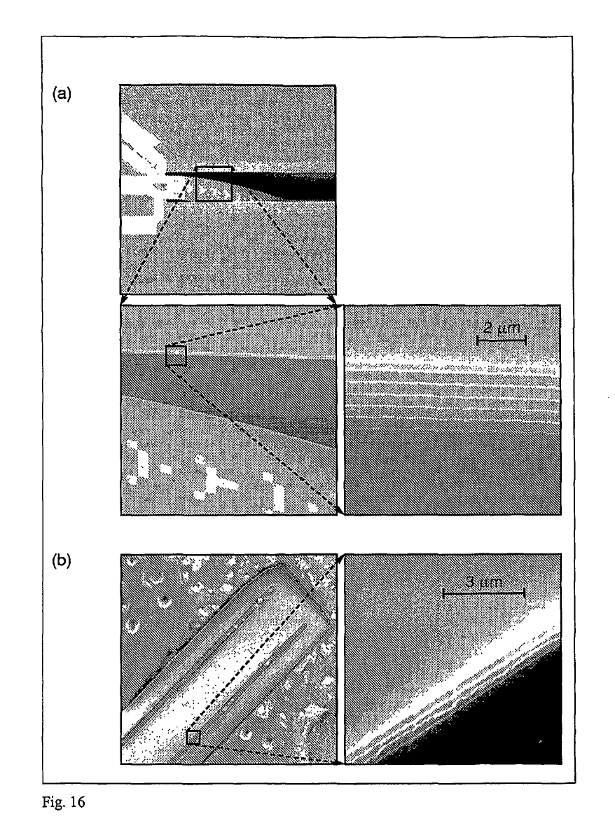

FIG. 16 is a montage of scanning electron microscope (SEM) images of the microfabricated device containing the reference cantilever using a primary energy of 20 keV. FIG. 16(a) shows the top surface of the cantilever. The cantilever has been pulled into contact with the glass substrate to allow the imaging of the edge of the membrane from which it is formed. This edge shows ripples characteristic of the Deep Reactive-Ion Etching (DRIE) process that formed it. FIG. 16(b) shows the underside of the reference cantilever. A patch of carbon-loaded adhesive conductive tape was first attached to the surface of the reference cantilever die, and then pulled off, taking the cantilever and some surrounding part of the membrane with it. The final SEM image in FIG. 16(b) confirms the quality of the electrochemical etch stop in giving rise to a smooth and geometrically precise surface on the underside of the cantilever.

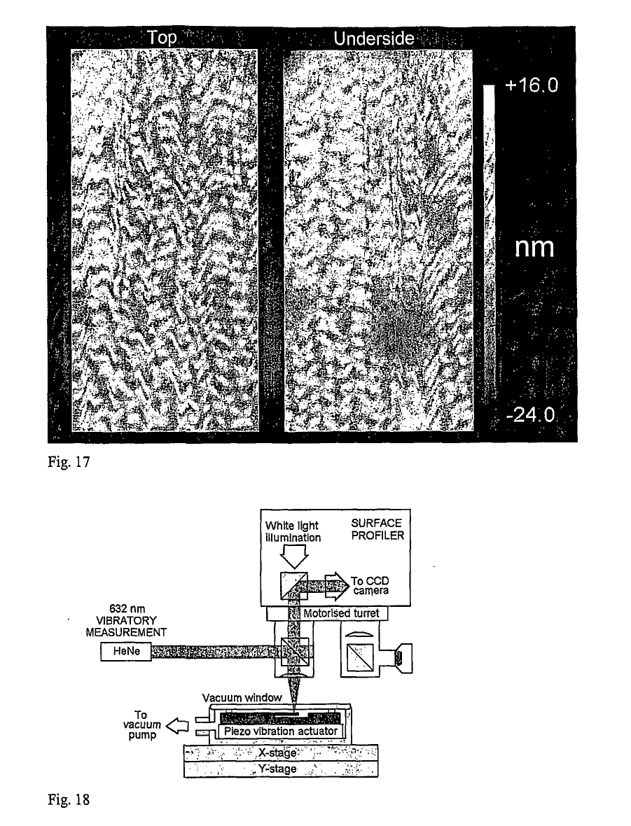

FIG. 17 shows topographic images of 200 μm×100 μm areas from the top of the die (beside the cantilever, and therefore having a similar surface roughness) and the underside of the cantilever (the surface that was bulk etched). Root-mean-square roughnesses are 0.9 nm and 6.5 nm for the top and underside of the cantilever respectively, well below the level that would be expected to lead to uncertainty in the comparison of spring constants. These topographic images were acquired by white-light interferometry.

Determining the Spring Constant of the Reference Cantilever

In order to use the reference cantilever for calibration purposes, it is necessary to determine its spring constant.

We now compare three different methods for determining the spring-constant at the end of the reference cantilever we have constructed.

In a so-called “diving-board” cantilever of sufficiently large length-to-breadth ratio (a condition which our reference cantilever fulfils), the spring constant at the end of the cantilever has been shown to be:
k_{E}=4π²κ_{Sader}mf² (1)
where κ_{Sader}=0.2427, m is the mass of the cantilever and f is its fundamental resonant frequency. This measurement was performed in vacuum by Doppler velocimetry to avoid correcting for resonance measurements in air.

The mass of the cantilever was estimated using its linear dimensions and a reference value for the density of silicon of 2330 kg m⁻³.

For a clamped cantilever undergoing small and therefore linear displacements, the spring constant at the end is given in terms of the Young's modulus, E, of the material by;

$${k}_{E} = \frac{{Ebt}^{3}}{4 {L}^{3}} \qquad ( 2 )$$

However, neither of these methods properly account for the boundary conditions at the base of the cantilever, because the cantilever is not clamped but cut within a membrane of the same 3 μm thickness. This is difficult to account for using analytical models giving equations in closed form, so instead finite-element calculations were performed using the ABAQUS Finite Element code within the Coventorware 2003 software package. The values for k_{E} calculated by these three methods for our reference cantilever are presented in Table 2.

TABLE 2
Spring constant at the end of the reference cantilever,
estimated by three methods.

| Method | Sader et al[9] | Euler-Bernoulli | Finite Elements |
|---|---|---|---|
| Defining equation | ${k}_{E} = 4 {π}^{2} {κ}_{Sader} {mf}^{2}$ | ${k}_{E} = \frac{{Ebt}^{3}}{4 {L}^{3}}$ | — |
| Value | 0.032 N/m | 0.030 N/m | 0.0295 N/m |

The average of the results of the three methods is used to give a value for the spring-constant (in this particular example of 0.0305N/m at the end of the reference cantilever).

Each reference cantilever must be individually calibrated through the measurement of its fundamental resonant frequency; this can be conveniently performed in high vacuum by sweeping the frequency of a vertical piezo vibrator while monitoring the vibration amplitude using the built-in piezoresistors. This is a purely electrical measurement taking less than one minute.

$${k}_{c} = {{k}_{E} ( \frac{{L}_{0}}{A + sD} )}^{3} \qquad ( 3 )$$

Where

k_{E}=0.0305±0.002 N/m is the spring constant at the end of the reference cantilever, L₀=1.6×10⁻³m is the length of the reference cantilever, A=3.2×10⁻⁵ m is the offset corresponding to the start of the lengthscale on the reference cantilever, and s=6.0×10⁻⁵ m is the interval between successive 5-bit binary codes on its surface.

Resonance Measurements

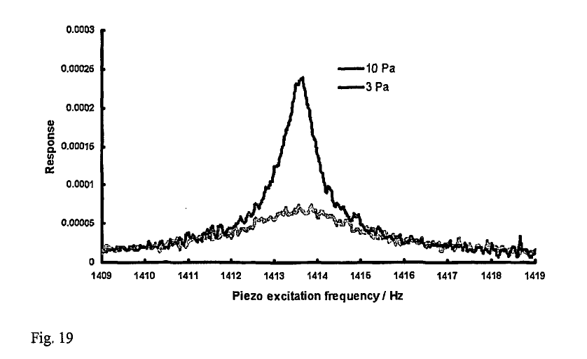

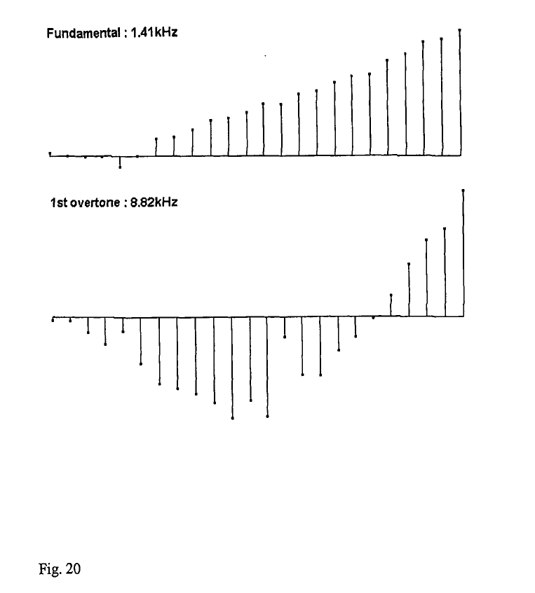

The resonant frequencies of the cantilever can be measured using built-in piezoresistors as displacement sensors. However it is useful, in establishing the performance of the cantilever (though probably not for the user of the device) to plot not simply the frequencies, but also the modes of vibration. The value of Sader's constant κ_{Sader} is valid only for the fundamental mode, so we must be completely confident that it is the fundamental mode that we are observing. Modes of vibration of the cantilever were identified using a Doppler laser vibrometer system as illustrated in FIG. 18. The cantilever chip was vibrated sinusoidally using a piezoelectric actuator, and the resonant frequencies of the cantilever determined. The fundamental resonance is shown in FIG. 19 for two different background pressures of 3 Pa and 10 Pa. The abscissa is proportional to the velocity amplitude of vibration near the end of the cantilever, and is in arbitrary units. One can see that the sharpness of the resonance increases substantially as the pressure decreases. Even at 10 Pa pressure, the large area of the cantilever means that damping is high. This is one of the reasons we observe no degradation of image quality during AFM imaging in air, even though the cantilever has a low resonant frequency. Conversely the measurement of its resonant frequencies (for example the fundamental frequency that is used in Sader's method of estimating cantilever spring constant) must be performed in vacuum, at a pressure below about 5 Pa, whether using the built-in piezoresistive sensors or the Doppler velocimetry technique of FIG. 19.

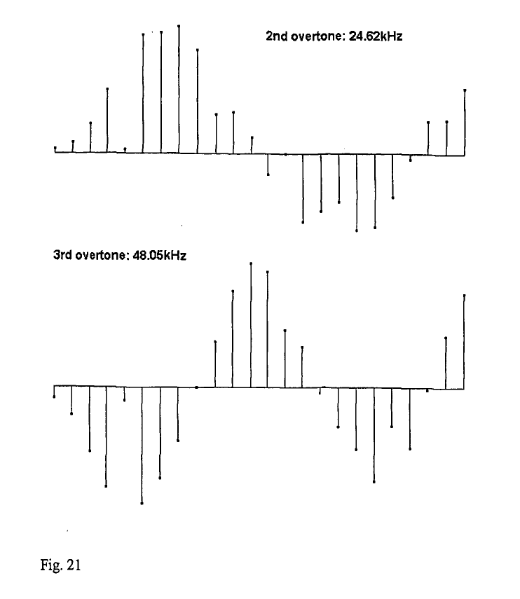

FIG. 20 shows experimentally measured modes of vibration of the reference cantilever. The fundamental mode corresponds to the resonant peak shown in FIG. 19. FIG. 21 shows experimental determinations of higher order modes of vibration of the reference cantilever.

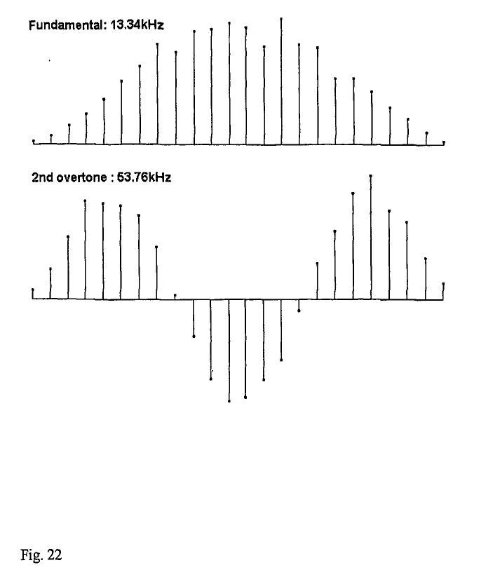

FIG. 22 shows the first two modes of vibration of the doubly-supported beam, determined experimentally by Doppler vibrometry.

Calibration Procedure

In one embodiment of the present invention, a two-point calibration method is used. The method uses the ratio of the slopes of two force distance curves—one pressing the AFM tip against a hard surface, one against the reference cantilever—to obtain a measurement of the AFM cantilever spring constant with an uncertainty of below 10%.

Before acquiring a force-distance curve using the reference cantilever, one is acquired for a hard surface, such as the neighbouring area of the chip consisting of silicon 0.4 mm thick. Since this surface is rigid, the increased deflection of the tip during acquisition of a force-distance curve is equal to the downward displacement of the cantilever by the tube scanner of the AFM, i.e.
Δδ_{Hard}=ΔZ_{Hard} (4)

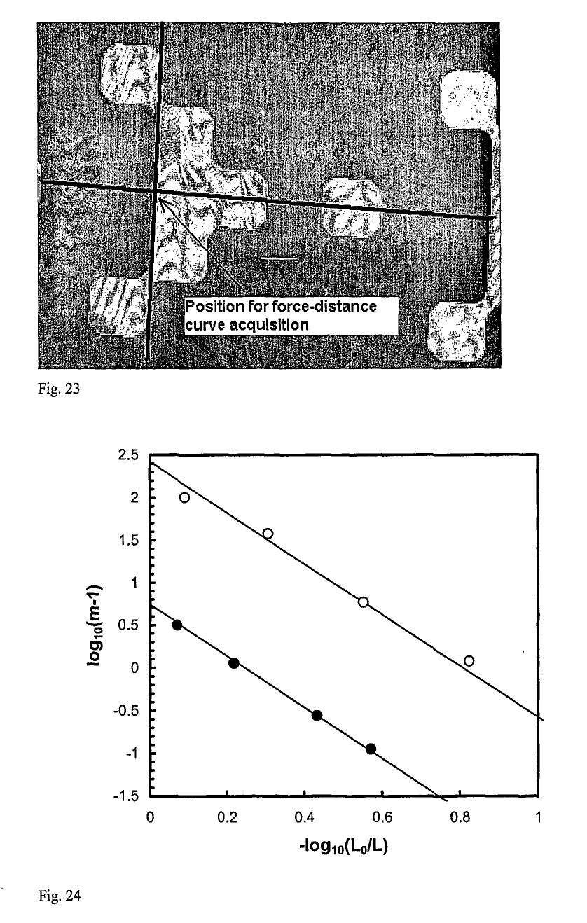

One then acquires a force-distance curve from the region of the reference cantilever having a spring constant k_{ref} close to the expected spring constant of the AFM cantilever being calibrated. After landing the AFM tip on the surface of the reference cantilever, acquire an image similar to that shown in FIG. 23. The AFM tip is moved to the middle of the axis of the code, at the base of the arrow.

The exact position of the base of this arrow can be determined from the five-bit binary code that follows it, as has been discussed above.

This expected value may come from the manufacturer's specification, or from previous calibrations of similar cantilevers. Thus for the force-distance curve acquired from this position on the reference cantilever;
αΔV_{RC}=ΔZ_{RC} (5)
where α is a constant depending on the cantilever and the laser spot position on the AFM cantilever (i.e. even for a single AFM cantilever it may change in a over a period of hours, making re-calibration necessary). In section II of the force-distance curve

$$α Δ {V}_{A - B}^{II} = \frac{{k}_{ref}}{{k}_{c} + {k}_{ref}} Δ {Z}^{II} \qquad ( 6 )$$

so we can eliminate α and calculate the spring constant of the cantilever from;

$${k}_{c} = {{k}_{E} ( \frac{{L}_{0}}{A + sD} )}^{3} [ \frac{( \frac{Δ {V}_{Hard}}{Δ {Z}_{Hard}} )}{( \frac{Δ {V}_{RC}}{Δ {Z}_{RC}} )} - 1 ] \qquad ( 7 )$$

Where

k_{E}=0.032±0.002N/m, L₀=1.6×10⁻³ m, A=3.2×10⁻⁵ m and s=6.0×10⁻⁵ m

To check the validity of this procedure we can rearrange this to

$$\begin{matrix}{log}_{10} ( m - 1 ) = {log}_{10} ( {k}_{c} / {k}_{E} ) - 3 {log}_{10} ( \frac{{L}_{0}}{L} ) \\ where & ( 8 ) \\ m = \frac{( \frac{Δ {V}_{Hard}}{Δ {Z}_{Hard}} )}{( \frac{Δ {V}_{RC}}{Δ {Z}_{RC}} )} & ( 9 )\end{matrix}$$

and L=A+sD. Therefore for a particular AFM cantilever we should expect a log-log plot of (m−1) against (L₀/L) to give a straight line of gradient −3 and intercept (k_{c}/k_{E}). FIG. 24 shows such a plot for two cantilevers, of nominal spring constant 0.5N/m and 2N/m. This calibration indicates the true spring constants of these AFM cantilevers to be 0.18N/m and 8.4N/m respectively.

FIG. 24 illustrates experimental AFM force-distance measurements for two AFM cantilevers. Each point represents the average of between four and six force-distance curve slopes. Open circles correspond to a cantilever quoted by the manufacturer as having a spring constant of 2N/m, and the filled circles to a cantilever quoted by the manufacturer as having a spring constant of 0.5N/m. This confirms the cubic dependence of reference cantilever spring constant with displacement along the cantilever. Theoretical best-fit straight lines have been given only one degree of freedom, since their slopes are fixed by theory.

The Effect of Air Damping

FIG. 19 gives convincing evidence that at atmospheric pressure (around 10⁵ Pa) we should expect the resonance of such a large reference cantilever to be heavily damped. This is a major advantage, since it allows us to

image the built-in length scale and

acquire force-distance curves free of oscillations

If not damped, the cantilever would be easily excited into resonance.

However the same air-damping will lead to a maximum rate at which force-distance curves can be acquired without the reference cantilever appearing to be “stiffened” by air resistance. The calibration force-distance curve of the AFM cantilever on the reference cantilever that must be acquired at below a critical speed. The following approximate analysis shows that the practical acquisition of force-distance curves by AFM never approaches this speed, and the reference cantilever can be used with confidence.

First recognise that the motion of the reference cantilever under the force applied by the AFM tip occurs at very low Reynolds number at atmospheric pressure, i.e.;

$$Re = \frac{ρ v D}{μ} \qquad ( 10 )$$

where Re is Reynold's number, v is the velocity of the cantilever, ρ≈1.24 kg m⁻³ is the density of air, D=150 μm is the characteristic dimension of the reference cantilever (its width) and μ=1.85×10⁻⁵ kg m⁻² is the dynamic viscosity of air. The velocity of the cantilever, v, typically corresponding to a displacement of the order of 100 nm over an interval of 1 s or so during acquisition of a force-distance curve, so that v≈1×10⁻⁷ m s⁻¹. This suggests a Reynold's number of around 10⁻⁶, meaning that the air resistance on the cantilever is almost completely viscous. Therefore we can estimate the viscous drag on the cantilever in a gross fashion using Stokes' law, and modelling the cantilever as a string of spheres with similar cross-sectional area;
F_{drag}=6πnηDv (11)
where n≈L/b≈11, so that F_{drag}≈0.1 pN. This is negligible compared to the reaction force being measured. This drag force scales in proportion to velocity, so that even acquiring a force-distance curve in 10 ms (beyond the ability of present day AFM and processing electronics) the viscous drag would result in a fairly constant 10 pN force on the reference cantilever. Even in this case the error introduced into the calibration would be much less than other uncertainties in the procedure. This shows that the practical calibration of AFM cantilevers by the “cantilever-on-cantilever” method never approaches a speed where air resistance becomes a source of error, even though air resistance has the positive effect of damping unwanted excitation of cantilever resonance. The reference cantilever can therefore be used with confidence.

There are a number of instruments similar to AFM that require force calibration, e.g. Nanoindentors, MEMS cantilever sensors and the like. It will be appreciated that the present invention is suitable for use in calibrating such instruments

1. A calibration device comprising a platform having a substantially planar surface suitable for the landing of an AFM cantilever tip, one or more supporting legs arranged to provide sprung resistance to the platform and a capacitive sensor for measuring a combined spring constant of the one or more supporting legs with respect to displacement substantially perpendicular to said substantially planar surface.

2. A calibration device according to claim 1, wherein the capacitive sensor further includes an actuator for setting the device into resonance.

3. A calibration device according to claim 1, further comprising a vibrator for setting the device into resonance.

4. A calibration device according to claim 3, wherein the vibrator is piezoelectric.

5. A calibration device according to claim 1, wherein the supporting legs comprise folded-beams.

6. A calibration device according to claim 1, wherein the capacitive sensor includes one or more interdigital comb drive capacitive actuators.

7. A calibration device according to claim 1, wherein the capacitive sensor comprises a Watt Balance device.

8. A method of determining the spring constant of a calibration device comprising the steps of:
a) providing the calibration device which includes a platform having a substantially planar surface suitable for the landing of an AFM cantilever tip, one or more supporting legs arranged to provide sprung resistance to the platform and a capacitive sensor for measuring a combined spring constant of the one or more supporting legs with respect to displacement substantially perpendicular to said substantially planar surface;
b) applying a predetermined vibration to the device and simultaneously measuring the velocity of the platform;
c) calculating the gradient of capacitance of the device in dependence on the measured velocity;
d) applying a predetermined voltage to the capacitive sensor and simultaneously measuring the static displacement of the platform; and,
e) calculating the spring constant in dependence on the gradient of capacitance and the measured displacement.

9. A method according to claim 8, wherein the static displacement is measured using white-light interferometry.

10. A method according to claim 8, wherein the velocity is measured using Doppler velocimetry.

11. A method according to any of claim 8, wherein steps b and d are performed in a vacuum.

12. A method of determining a spring constant of an AFM cantilever comprising the steps of:
a) determining deflection of the cantilever when pressed against a solid surface;
b) determining deflection of the cantilever when pressed against a calibration device having a predetermined spring constant, wherein the calibration device includes a platform having a substantially planar surface suitable for the landing of an AFM cantilever tip, one or more supporting legs arranged to provide sprung resistance to the platform and a capacitive sensor for measuring a combined spring constant of the one or more supporting legs with respect to displacement substantially perpendicular to said substantially planar surface; and,
c) calculating the spring constant of the AFM cantilever from the ratio of the two deflections multiplied by the predetermined spring constant.

13. (canceled)

14. (canceled)

15. (canceled)

16. (canceled)

17. (canceled)

18. (canceled)

19. (canceled)

20. (canceled)

21. (canceled)

22. A calibration device as claimed in claim 1 incorporated into an AFM cantilever.

23. A calibration device according to claim 1 incorporated into a reference cantilever useable for calibrating small force measuring devices.

24. A calibration device according to claim 23, wherein the reference cantilever includes a length scale visible in AFM images.
